(19) United States
(12) Patent Application Publication
(10) Pub. No.: US 2025/0285613 A1
(43) Pub. Date: Sep. 11, 2025

(54) QUANTIZATION METHOD AND APPARATUS FOR SPEECH RECOGNITION MODEL, ELECTRONIC DEVICE, AND PRODUCT

(71) Applicant: Beijing Zitiao Network Technology Co., Ltd., Beijing (CN)

(72) Inventors: Fanliu Kong, Beijing (CN); Hongmin Xu, Beijing (CN); Yi Guo, Beijing (CN); Yiqian He, Beijing (CN); Xiaoyang Li, Beijing (CN); Wei Chen, Beijing (CN); Xiaogang Tian, Beijing (CN); Yang Zhang, Beijing (CN); Shouda Liu, Beijing (CN)

(21) Appl. No.: 18/972,493

(22) Filed: Dec. 6, 2024

(30) Foreign Application Priority Data
Mar. 6, 2024 (CN) 202410257364.1

(51) Int. Cl. G10L 15/14; G10L 15/065

(52) U.S. Cl. CPC G10L 15/14; G10L 15/065

(57) ABSTRACT

Embodiments of the present disclosure relate to a quantization method and apparatus for a speech recognition model, an electronic device, and a product. The method comprises determining a weight matrix for a network layer of the speech recognition model, where the weight matrix includes a plurality of blocks divided into a plurality of groups. The method further comprises adjusting an order of the plurality of blocks in the weight matrix according to the plurality of groups and based on a plurality of block parameters of the plurality of blocks, where the block parameter indicates how much a corresponding block affects the speech recognition model. The method further comprises quantizing the plurality of blocks in the adjusted weight matrix according to the adjusted order. In addition, the method further comprises restoring the order of the plurality of blocks in the quantized weight matrix.

### CROSS-REFERENCE TO RELATED APPLICATION(S)

This application claims priority to Chinese Application No. 202410257364.1 filed Mar. 6, 2024, the disclosure of which is incorporated herein by reference in its entirety.

### FIELD

The present disclosure generally relates to the field of computers, and more particularly, to a quantization method and apparatus for a speech recognition model, an electronic device, and a product.

### BACKGROUND

In natural language processing (NLP for short), a neural network model using massive parameters (hundreds of millions of parameters) has achieved breakthroughs in a plurality of tasks. However, an increase in the number of parameters of the neural network model and an improvement in the model capabilities come at the cost of an increase in the graphics memory usage, computational complexity, etc.

In order to reduce deployment costs (e.g., inference time, model throughput, graphics memory usage, etc.) of a large-scale neural network model during the deployment of the model, model parameter quantization becomes an important means of optimizing the model. Quantization refers to representing a numerical value range of an original model parameter with low bits from the systematic perspective, while achieving an algorithmic effect similar to that of the original model. Therefore, how to quantize the model becomes a crucial problem in the field of natural language processing.

### SUMMARY

Embodiments of the present disclosure provide a quantization method and apparatus for a speech recognition model, an electronic device, and a product.

According to a first aspect of the present disclosure, there is provided a quantization method for a speech recognition model. The method comprises determining a weight matrix for a network layer of the speech recognition model, where the weight matrix includes a plurality of blocks divided into a plurality of groups. The method further comprises adjusting an order of the plurality of blocks in the weight matrix according to the plurality of groups and based on a plurality of block parameters of the plurality of blocks, where the block parameter indicates how much a corresponding block affects the speech recognition model. The method further comprises quantizing the plurality of blocks in the adjusted weight matrix according to the adjusted order. In addition, the method further comprises restoring the order of the plurality of blocks in the quantized weight matrix.

According to a second aspect of the present disclosure, there is provided a quantization apparatus for a speech recognition model. The apparatus comprises a weight matrix determination module configured to determine a weight matrix for a network layer of the speech recognition model, where the weight matrix includes a plurality of blocks divided into a plurality of groups. The apparatus further comprises a block order adjustment module configured to adjust an order of the plurality of blocks in the weight matrix according to the plurality of groups and based on a plurality of block parameters of the plurality of blocks, where the block parameter indicates how much a corresponding block affects the speech recognition model. The apparatus further comprises a block quantization module configured to quantize the plurality of blocks in the adjusted weight matrix according to the adjusted order. In addition, the apparatus further comprises a block order restoration module configured to restore the order of the plurality of blocks in the quantized weight matrix.

According to a third aspect of the present disclosure, there is provided an electronic device. The electronic device comprises a processor and a memory coupled to the processor, where the memory has instructions stored therein, which, when executed by the processor, cause the electronic device to perform the method according to the first aspect.

According to a fourth aspect of the disclosure, there is provided a computer program product including computer-executable instructions, where the computer-executable instructions are executed by a processor to implement the method according to the first aspect.

According to a fifth aspect of the present disclosure, there is provided a computer-readable storage medium. The computer-readable storage medium has computer-executable instructions stored thereon, where the computer-executable instructions are executed by a processor to implement the method according to the first aspect.

The section Summary is provided to introduce a selection of concepts in a simplified form, which will be further described in the detailed description below. The section Summary is neither intended to identify key features or principal features of the claimed subject matter, nor to limit the scope of the claimed subject matter.

### BRIEF DESCRIPTION OF THE DRAWINGS

The foregoing and other features, advantages and aspects of embodiments of the present disclosure become more apparent with reference to the following detailed description and in conjunction with the accompanying drawings. Throughout the accompanying drawings, the same or similar reference numerals denote the same or similar elements, in which:

FIG. 1 is a schematic diagram of an example environment in which some embodiments of the present disclosure can be implemented;

FIG. 2 is a flowchart of a quantization method for a speech recognition model according to some embodiments of the present disclosure;

FIG. 3 is a schematic diagram of a method for grouping blocks in a weight matrix according to some embodiments of the present disclosure;

FIG. 4 is a schematic diagram of a process of performing group adjustment for a weight matrix according to some embodiments of the present disclosure;

FIG. 5 is a flowchart of another quantization method for a speech recognition model according to some embodiments of the present disclosure;

FIG. 6 is a block diagram of a quantization apparatus for a speech recognition model according to some embodiments of the present disclosure; and

FIG. 7 is a block diagram of an electronic device according to some embodiments of the present disclosure.

Throughout the accompanying drawings, the same or similar reference numerals denote the same or similar elements.

### DETAILED DESCRIPTION OF EMBODIMENTS

It can be understood that the data involved in the technical solutions (including, but not limited to, the data itself and the access to or use of the data) shall comply with the requirements of corresponding laws, regulations, and relevant provisions.

It can be understood that before the use of the technical solutions disclosed in the embodiments of the present disclosure, the user shall be informed of the type, range of use, use scenarios, etc., of personal information involved in the present disclosure in an appropriate manner in accordance with the relevant laws and regulations, and the authorization of the user shall be obtained.

For example, upon reception of an active request from the user, prompt information is sent to the user to clearly inform the user that a requested operation will require access to and use of the personal information of the user. As such, the user can independently choose, based on the prompt information, whether to provide the personal information to software or hardware, such as an electronic device, an application, a server, or a storage medium, that performs operations in the technical solutions of the present disclosure.

As an optional but non-limiting implementation, in response to the reception of the active request from the user, the prompt information may be sent to the user in the form of, for example, a pop-up window, in which the prompt information may be presented in text. In addition, the pop-up window may further include a selection control for the user to choose whether to “agree” or “disagree” to provide the personal information to the electronic device.

It can be understood that the above process of notifying and obtaining the authorization of the user is only illustrative and does not constitute a limitation on the implementations of the present disclosure, and other manners that satisfy the relevant laws and regulations may also be applied in the implementations of the present disclosure.

The embodiments of the present disclosure are described in more detail below with reference to the accompanying drawings. Although some embodiments of the present disclosure are shown in the accompanying drawings, it should be understood that the present disclosure may be implemented in various forms and should not be construed as being limited to the embodiments set forth herein. Rather, these embodiments are provided for a more thorough and complete understanding of the present disclosure. It should be understood that the accompanying drawings and the embodiments of the present disclosure are only for exemplary purposes, and are not intended to limit the scope of protection of the present disclosure.

In the description of the embodiments of the present disclosure, the term “include” and similar terms should be understood as open-ended inclusion, namely, “including but not limited to”. The term “based on” should be understood as “at least partially based on”. The term “an embodiment” or “the embodiment” should be understood as “at least one embodiment”. The terms “first”, “second”, and the like may refer to different objects or the same object, unless otherwise explicitly defined. Other explicit and implicit definitions may also be included below.

As described above, the core point of optimizing a speech recognition model lies in: significantly reducing deployment costs of an optimized model while maintaining the same effect as an original model. Low-bit quantization is an important optimization method for the speech recognition model. The low-bit quantization method uses low bits (for example, 1/2/4/8 bits) to represent a numerical value range of parameters (for example, 16/32 bits) of the original model from the systematic perspective, while achieving an algorithmic effect matching the original model. An optimized low-bit model can significantly reduce the graphics memory usage, and increase the computational speed of specific hardware, and speed up inference.

Related quantization methods comprise quantization-aware training (QAT for short) and post-training quantization (PTQ for short). The post-training quantization method features short optimization time, no need for further training, few sample data needed, and thus becomes a mainstream method for neural network model quantization. In the related method, the post-training quantization method is directly applied to the speech recognition model for model quantization. However, due to properties of data in the field of speech recognition and irregularities of a distribution of parameters in the speech recognition model, direct quantization of model parameters may result in a poor quantization effect, thereby affecting the performance of a quantized speech recognition model.

In the embodiments of the present disclosure, a weight matrix for a network layer is first extracted from a speech recognition model to be quantized, and blocks (for example, row blocks or column blocks) in the weight matrix are divided into a plurality of groups. Then, based on a degree of influence of each block on performance of the speech recognition model, an importance degree (which may be referred to as a block parameter) of the corresponding block is determined, and an order of the blocks in the weight matrix is adjusted according to the plurality of groups and based on the importance degree of each block. Further, each matrix in the weight matrix is quantized according to the adjusted order, and after the quantization is completed, the order of the blocks in the weight matrix is adjusted to the initial order. In this way, during a model weight quantization process, a weight with a higher importance degree in a group can be quantized first, to reduce losses in the quantization process and improve the overall quantization parameter of model weight, thereby alleviating the impact of quantization on performance of the speech recognition model.

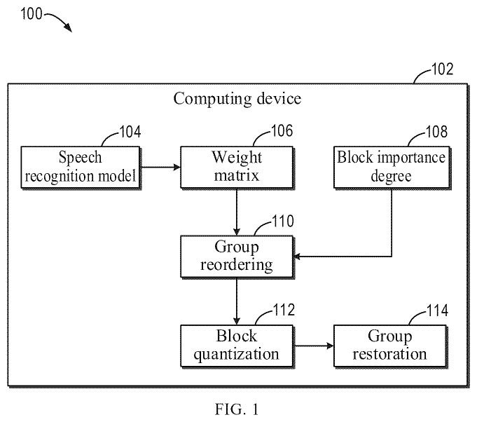

FIG. 1 is a schematic diagram of an example environment 100 in which some embodiments of the present disclosure can be implemented. Referring to FIG. 1, the example environment 100 includes a computing device 102, where the computing device 102 may be provided as a computing system, a single server, a distributed server, a cloud-based server, or the like.

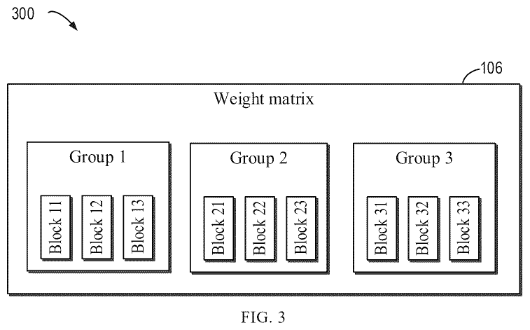

In some embodiments, the computing device 102 computes a weight matrix 106 for a network layer of a speech recognition model 104, where blocks in the weight matrix 106 are divided into a plurality of groups. Then, at block 110, the computing device 102 performs group reordering, to adjust an order of the blocks in the weight matrix 106 according to the plurality of groups and based on block importance degrees 108 (which may be referred to as block parameters) of the blocks in the weight matrix 106. The process of dividing the weight matrix into the plurality of groups and adjusting the order of the blocks according to the plurality of groups will be described below in conjunction with FIG. 3, and details are not described here.

In some embodiments, the speech recognition model 104 is a large language model (LLM for short) that integrates a speech recognition function. It may be understood that the large language model has a large number of parameters. As the number of parameters in the large language model increases, the model performance is also improved. There are even some large language models with a parameter size much larger than that of previous typical industrial models, resulting in a sharp increase in the graphics memory usage, computational complexity, etc. of the computing device 102. When not quantized, the large language model is deployed in the computing device 102 at excessive costs.

In some embodiments, at block 112, the computing device 102 performs block quantization, to quantize the blocks in the weight matrix 106 according to the adjusted order of the blocks in the weight matrix 106. Then, after the computing device 102 completes the quantization of the weight matrix 106, at block 114, the computing device 102 performs group restoration to adjust the order of the blocks in the quantized weight matrix 106 to an initial order.

In this way, during the process of the computing device 102 quantizing the weight matrix 106 for the speech recognition model 104, a weight of a block that has a higher importance degree in a group can be quantized first, to reduce losses in compressing the weight from high precision to low precision during the quantization process and improve the overall quantization effect of the speech recognition model 104, thereby alleviating the impact of quantization on performance of the speech recognition model 104.

It should be understood that the architecture and function in the example environment 100 are described for exemplary purposes only, rather than for implying any limitation on the scope of the present disclosure. The embodiments of the present disclosure may also be applied to other environments with different structures and/or functions.

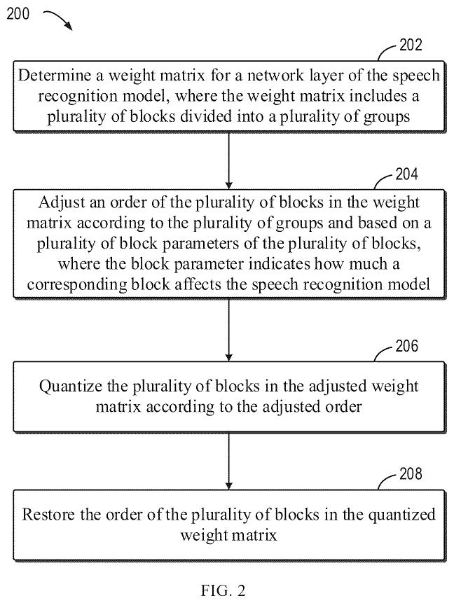

The process according to the embodiments of the present disclosure will be described in detail below in conjunction with FIG. 2 to FIG. 8. For ease of understanding, all the specific data mentioned in the following description is exemplary, and is not intended to limit the scope of protection of the present disclosure. It may be understood that the embodiments described below may further include additional actions not shown and/or may omit actions shown, and the scope of the present disclosure is not limited in this regard.

FIG. 2 is a schematic flowchart of a quantization method 200 for a speech recognition model according to some embodiments of the present disclosure. In some embodiments, the quantization method 200 for a speech recognition model may be performed by the computing device 102 shown in FIG. 1. It should be understood that the computing device 102 may be provided as a computing system, a single server, a distributed server, a cloud-based server, or the like.

At block 202, a weight matrix for a network layer of the speech recognition model is determined, where the weight matrix includes a plurality of blocks divided into a plurality of groups. Referring to FIG. 1, in some embodiments, the speech recognition model 104 may be a neural network model used for processing an audio signal and generating corresponding text, or may be an integrated model with a speech recognition function (for example, a large language model integrating speech recognition, or a multi-modal neural network model including speech input).

In some embodiments, the weight matrix 106 is a matrix composed of a plurality of sets of weight parameters of multiple nodes of the network layer in the speech recognition model 104, and the blocks (for example, row blocks or column blocks) in the weight matrix 106 are divided into a plurality of groups at a certain granularity. For example, the weight matrix 106 is a 9×9 matrix, which divides the weight matrix 106 into three groups with a granularity of three row blocks. It should be understood that for ease of description, an order adjustment process, a group quantization process, etc. for the weight matrix are described below by using the column blocks as an example, but implementations related to the row blocks also fall within the scope of the present disclosure.

At block 204, an order of the plurality of blocks in the weight matrix is adjusted according to the plurality of groups and based on a plurality of block parameters of the plurality of blocks, where the block parameter indicates how much a corresponding block affects the speech recognition model. Referring to FIG. 1, in some embodiments, the block parameter is determined based on the degree of influence of the corresponding block on the performance of the speech recognition model 104, and may be set as the block importance degree 108. According to the block importance degree 108, a block with a higher importance degree may be sorted in front of a plurality of blocks in the corresponding group, or a group with a higher importance degree may be sorted in front of a plurality of groups, which ensures that the block and group with a higher quantization degree can be quantized first.

At block 206, the plurality of blocks in the adjusted weight matrix are quantized according to the adjusted order. Referring to FIG. 1, in some embodiments, after reordering the blocks in the weight matrix 106, the computing device 102 may quantize the blocks in the weight matrix 106 according to the adjusted order, to compress the weight in the block from a high-precision floating point number to a low-precision integer number. For example, 4-bit or 8-bit quantization may be performed on the weight in the block.

At block 208, the order of the plurality of blocks in the quantized weight matrix is restored. Referring to FIG. 1, in some embodiments, the computing device 102 restores the order of blocks in the weight matrix 106 to an initial order of the blocks based on a correspondence between an unadjusted block order and an adjusted block order, thereby ensuring the correspondence between a weight parameter in the network layer corresponding to the speech recognition model 104 and input data.

In the embodiment of the present disclosure, the weight matrix for the network layer is first extracted from the speech recognition model to be quantized, and the blocks in the weight matrix are divided into the plurality of groups. Then, based on a degree of influence of each block on performance of the speech recognition model, an importance degree of the corresponding block is determined, and the order of the blocks in the weight matrix is adjusted according to the plurality of groups and based on the importance degree of each block. Further, each matrix in the weight matrix is quantized according to the adjusted order, and after the quantization is completed, the order of the blocks in the weight matrix is adjusted to the initial order. In this way, during a model weight quantization process, a weight with a higher importance degree in a group can be quantized first, to reduce losses in the quantization process and improve the overall quantization parameter of model weight, thereby alleviating the impact of quantization on performance of the speech recognition model.

FIG. 3 is a schematic diagram of a method 300 for grouping blocks in a weight matrix according to some embodiments of the present disclosure. In some embodiments, the weight matrix 106 includes nine blocks, and every three blocks are used as one group, resulting in three groups in the weight matrix 106: a group 1, a group 2, and a group 3. The group 1 includes a block 11, a block 12, and a block 13, the group 2 includes a block 21, a block 22, and a block 23, and the group 3 includes a block 31, a block 32, and a block 33. It should be understood that the description of the number of blocks and the grouping manner in this embodiment does not impose a limitation on the weight matrix in the present disclosure.

In some embodiments, when determining an importance degree (which may be referred to as a block parameter) of the column block in the weight matrix 106, the computing device 102 may compute a second derivative of a weight in the weight matrix based on a relationship between input data, the weight matrix, and output data in the network layer. It should be understood that the second derivative reflects a local curvature condition and may be used to measure the importance degree of influence of the weight on the speech recognition model 104.

In some embodiments, the input data in the network layer of the speech recognition model 104 includes a plurality of input matrices. It should be understood that the input data is intermediate data for the speech recognition model 104. In some embodiments, the computing device 102 randomly collects several training samples from original training data, then inputs the training samples into the trained speech recognition model 104, and collects and saves the input data in the network layer to be quantized from speech recognition model 104.

In some embodiments, first, the computing device 102 obtains the plurality of input matrices of the network layer, and computes a plurality of transpose matrices corresponding to the plurality of input matrices. Then, the computing device 102 computes an average of a plurality of products of the plurality of input matrices and the plurality of corresponding transpose matrices, and uses the average of the plurality of products as a second derivative matrix. Further, each diagonal element of the second derivative matrix is determined as an importance degree of a corresponding column block in the weight matrix 106. In some embodiments, an importance degree of each weight in the column block is the diagonal element. In this way, a second derivative of the column block can be quickly determined, which avoids linear fitting and second derivation of the weight matrix 106, increasing the speed of determining the importance degree of the column block, and thus improving the efficiency of adjusting an order of column blocks.

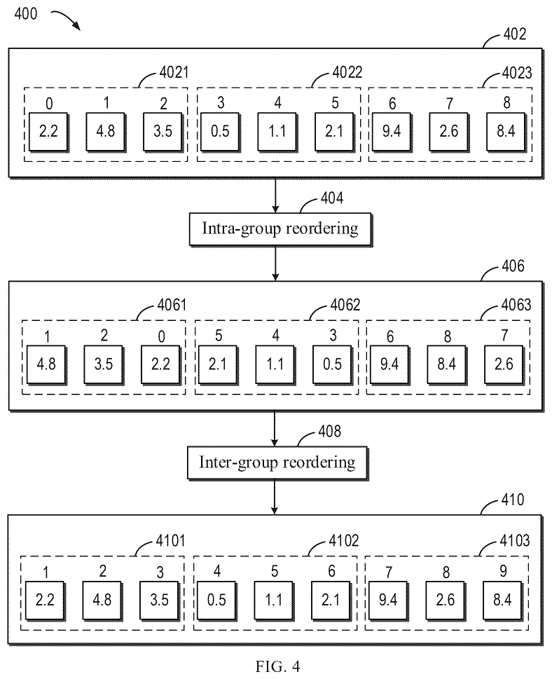

FIG. 4 is a schematic diagram of a process 400 of performing group adjustment for a weight matrix according to some embodiments of the present disclosure. In some embodiments, the second derivative matrix has dimensions 9×9, with diagonal elements 402 including nine elements with index numbers 0 to 8 shown in FIG. 4, including 2.2, 4.8, 3.5, 0.5, 1.1, 2.1, 9.4, 2.6, and 8.4. It should be understood that the nine elements in the diagonal elements 402 are respectively block importance degrees of the block 11, the block 12, the block 13, the block 21, the block 22, the block 23, the block 31, the block 32, and the block 33 shown in FIG. 3, and the group 1, the group 2, and the group 3 respectively correspond to three groups of the diagonal elements 402: an element group 4021, an element group 4022, and an element group 4023.

In some embodiments, after grouping of the blocks in the weight matrix 106, the computing device 102 first determines an importance degree sorting result (which may be referred to as a first sorting result) of blocks in each group. In particular, at block 404, the computing device 102 performs intra-group reordering on the diagonal elements 402, to sort elements in the element group 4021, the element group 4022, and the element group 4023 respectively in descending order, resulting in diagonal elements 406. In the diagonal elements 406, the element group 4021, the element group 4022, and the element group 4023 are respectively reordered as an element group 4061, an element group 4062, and an element group 4063. It should be understood that orders of elements in the element group 4061, the element group 4062, and the element group 4063 are sorting results of blocks in the group 1, the group 2, and the group 3. Then, according to the sorting results of the blocks in the group 1, the group 2, and the group 3, the computing device 102 adjusts an order of the blocks in each group.

In some embodiments, the computing device 102 further computes averages of the element group 4061, the element group 4062, and the element group 4063 based on the elements in the element group 4061, the element group 4062, and the element group 4063. The averages of the element group 4061, the element group 4062, and the element group 4063 are respectively group parameters of the group 1, the group 2, and the group 3. Then, the computing device 102 sorts the element group 4061, the element group 4062, and the element group 4063 in descending order based on the averages of the element group 4061, the element group 4062, and the element group 4063, resulting in diagonal elements 410. It should be understood that a sorting result for an element group 4101, an element group 4102, and an element group 4103 in the diagonal elements 410 is a sorting result (which may be referred to as a second sorting result) for the group 1, the group 2, and the group 3. Then, the computing device 102 adjusts an order of the groups in the weight matrix 106 according to the sorting result for the group 1, the group 2, and the group 3.

In this way, a group with a higher importance degree in the weight matrix 106 may be sorted in front of a plurality of groups, and a block with a higher importance degree in each group may be sorted in front of a plurality of blocks, thereby ensuring that during quantization, the group and block with a higher importance degree can be quantized first, and thus improving the overall quantization precision. In addition, sorting the blocks in the weight matrix 106 in unit of a group can ensure the continuity of the quantization process and thus improve the quantization efficiency.

In some embodiments, the computing device 102 sequentially quantizes each column block in the weight matrix 106 in an iterative mode. During an iteration, a current column block (which may be referred to as a first column block) is quantized first, and then unquantized column blocks in the weight matrix 106 are optimized based on the second derivative matrix, to complete the iteration for one-time quantization. During a next iteration, the column block sorting first in the optimized unquantized column blocks is selected and quantized, and then the remaining unquantized column blocks are optimized again. In this way, the remaining unquantized column blocks can be optimized during column-by-column quantization, thereby reducing quantization losses and improving the quantization quality.

In some embodiments, prior to the process of quantizing the column block in the weight matrix 106, the computing device 102 first determines a quantization parameter (which may be referred to as a first quantization parameter) corresponding to each group in the weight matrix 106, where the quantization parameter includes a scale (which may be referred to as a first scale) that represents quantization from high bits to low bits and a zero point (which may be referred to as a first offset) that represents an offset caused during the quantization. Then, in the process of quantizing a block, the computing device 102 first determines a group to which the block belongs, and then quantizes the block based on a quantization parameter corresponding to the group, and the above iteration is repeated.

In this way, blocks may be quantized in unit of a group based on a quantization parameter for the group in the weight matrix 106, thereby ensuring quantization continuity during quantization of the plurality of blocks in the group, and continuity of scales and zero points, alleviating the impact on continuity of inference during the quantization, and thus improving the efficiency of quantizing the weight matrix 106.

In some embodiments, during the process of determining the scale for each group in the weight matrix 106, the computing device 102 first determines a difference between a maximum weight and a minimum weight in the group, and then determines a quantization range for the group in a required quantization manner. In some embodiments, the quantization manner is determined based on bits to which quantization is required. For example, if the weight is to be quantized to 4 bits, a corresponding quantization range is 15. Further, the computing device 102 computes the scale for the group based on the difference between the maximum weight and the minimum weight and the quantization range. It should be understood that the scale reflects the length of variation of a weight in the group that can be represented by each unit value in the bits to which the quantization is required.

In some embodiments, after determining the scale for each group, the computing device 102 computes a ratio of the weight in each group to the scale. It may be understood that a ratio computation result indicates a matrix with the same dimension as the group. Then, the computing device 102 rounds each ratio in the ratio computation result to obtain rounding results, and determines a minimum rounding result from the rounding results. It may be understood that the rounding result also indicates a matrix with the same dimension as the group. Further, the computing device 102 determines the zero point for the group based on a ratio of the minimum rounding result to the scale.

In some embodiments, during iteration of quantizing the blocks in the weight matrix 106, the computing device 102 may further perform fake quantization on the quantized block based on the quantization parameter, to simulate the precision of a weight parameter in the speech recognition model 104 at high bits. Moreover, the quantized block has a weight and the quantization parameter deployed and read at a much lower cost than the high-bit weight parameter, thus making it also possible to reduce a device cost while ensuring the model precision of the speech recognition model 104.

Then, for the weight matrix 106 subjected to the fake quantization, the order of the blocks in the weight matrix 106 may be restored first, and then the weights in the order-restored weight matrix 106 are quantized based on a quantization parameter (which may be referred to as a second quantization parameter) including a scale (which may be referred to as a second scale) and a zero point (which may be referred to as a second offset), to compress the order-restored weight matrix 106.

In some embodiments, during quantization of the order-restored weight matrix 106, the computing device 102 may quantize the blocks in each group according to the restored order for the group. During the process of quantizing each group, the computing device 102 first determines a quantization parameter corresponding to the group, and then quantizes the first block in the group based on the quantization parameter. Then, the computing device 102 continues to quantize the second block in the group based on the quantization parameter.

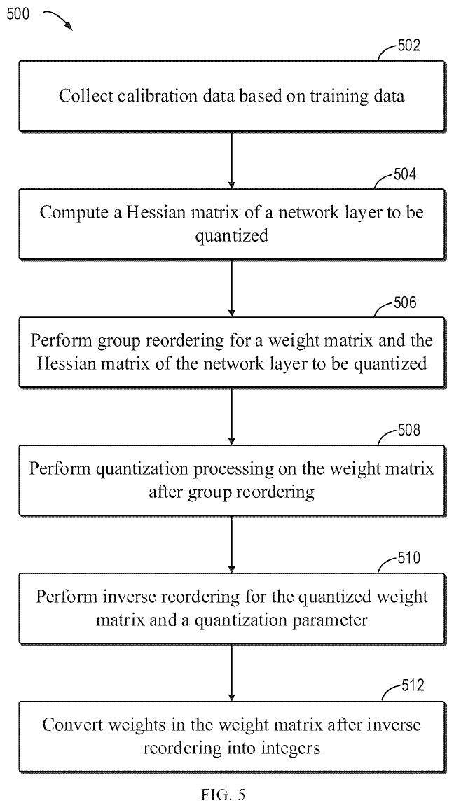

FIG. 5 is a flowchart of another quantization method 500 for a speech recognition model according to some embodiments of the present disclosure. In some embodiments, the quantization method 500 may be performed by the computing device 102 shown in FIG. 1. It should be understood that the computing device 102 may be provided as a computing system, a single server, a distributed server, a cloud-based server, or the like.

At block 502, the computing device 102 collects calibration data based on training data. In some embodiments, the computing device 102 randomly collects several pieces of sample data from the training data, then inputs the sample data into the trained speech recognition model 104, and extracts and stores, as the calibration data, input data in the network layer to be quantized through the speech recognition model 104. It should be understood that the calibration data is used to determine the importance degree of the column block in the weight matrix 106 and optimize the unquantized column blocks during the quantization.

At block 504, the computing device 102 computes a Hessian matrix (which may be referred to as a second derivative matrix) of the network layer to be quantized. In some embodiments, the Hessian matrix is computed as shown in formula (1):

$$H = \frac{1}{N} {\sum }_{i = 1}^{N} 2 {X}_{i} {X}_{i}^{T} \qquad ( 1 )$$

where N is the number of samples of the calibration data, i is a serial number of the calibration data, X and X^{T} are the calibration data (which is represented by a matrix) and a transpose of the calibration data, the calibration data has an input dimension of K, and the Hessian matrix H has dimensions K×K.

At block 506, the computing device 102 performs group reordering for the weight matrix and the Hessian matrix of the network layer to be quantized. In some embodiments, the computing device 102 first groups diagonal elements of the Hessian matrix, then sorts elements in each group in descending order, performs inter-group sorting for each group in descending order based on an average of each group, and finally adjusts the weight matrix and the Hessian matrix according to a mapping relationship between an index of a diagonal element before sorting and an index of the diagonal element after sorting. The adjusted weight matrix Wᵣ and Hessian matrix Hᵣ are respectively as shown in formula (2) and formula (3):

$${W}_{r} [ : , i ] = W [ : , r [ i ] ] \qquad ( 2 )$$

$${H}_{r} [ i , 1 ] = H [ r [ i ] , r [ j ] ] \qquad ( 3 )$$

where W is a weight matrix with dimensions N×K, i and j are respectively indexes of a row and a column, and i, j=0, 1, . . . , K.

After the adjusted Hessian matrix Hᵣ is determined, a constant 2 is added to diagonal elements of the Heisen matrix Hᵣ. For example, 2 may be set to 1% of an average of the diagonal elements. Further, a Cholesky decomposition of an inverse matrix of the Hessian matrix Hᵣ is computed as shown in formula (4):

$${H}^{- 1} = {Cholesky ( {( {H}_{r} + λ I )}^{- 1} )}^{T} \qquad ( 4 )$$

At block 508, the computing device 102 performs quantization processing on the weight matrix after group reordering. In some embodiments, the computing device 102 performs post-training quantization processing on the reordered weight matrix. A quantized weight matrix is set to W_{Q}, a quantization error matrix is set to Wₑ, and the column block has a size of B. Therefore, pseudo code for post-training quantization of the weight matrix Wᵣ is as follows:

```
Wₑ ← 0_{N*B}
W_{q} ← 0_{N*k}
for i = 0, B, 2B, ••• do
  for j = i,i + 1, ••• , i + B − 1, do
    W_{q}[:,j] ← FakeQuant(Wᵣ[:,j])
    Wₑ[:,j − i] ← Wᵣ[:,j] − W_{q}[:,j]/H⁻¹ [j,j]
    Wᵣ[:,j: (i + B)] ← Wᵣ [:,j: (i + B)] − Wₑ[:,j − i] · H⁻¹ [j,j: (i + B)]
  End for
  Wᵣ[:, (i + B):] ← Wᵣ[:, (i + B):] − Wₑ · H⁻¹[i: (i + B), (i + B):]
End for
```

where FakeQuant( ) represents fake quantization on the column block, which is computed as shown in formula (5):

$$FakeQuant ( x ) = clamp \{ round [ ( ( x - zero ) ) / scale ] , - 8 , 7 \} * scale + zero \qquad ( 5 )$$

where scale is a scaling factor, zero is a zero point, round( ) is a rounding function, and clamp(⋅, min, max) represents a truncation function truncated to within a range [min, max].

In some embodiments, during the process of quantizing the column block, one scaling factor scale and one zero point zero are computed for the weight of each group by means of group quantization. The scaling factor scale and the zero point zero are computed as shown in formula (6) and formula (7):

$${scale}_{r} [ i , j ] = [ max ( {W}_{r} [ i , j * G : ( j + 1 ) * G ] ) - min ( {W}_{r} [ i , j * G : ( j + 1 ) * G ] ) ] / 15 \qquad ( 6 )$$

$${zero}_{r} [ i , j ] = [ 8 + min ( round ( {W}_{r} [ i , j * G : ( j + 1 ) * G ] / {scale}_{r} [ i , j ] ) ) ] * {scale}_{r} [ i , j ] \qquad ( 7 )$$

where G is the size of the group, i is a row index, j is an index of a column group, and i=0, 1, . . . , N, j=0, 1, . . . , K/G.

At block 510, the computing device 102 performs inverse reordering for the quantized weight matrix and a quantization parameter. In some embodiments, a weight matrix W_{fq}, scaling factor scale, and zero point zero after inverse reordering are computed respectively as shown in formula (8), formula (9), and formula (10):

$${W}_{fq} [ : , i ] = {W}_{q} [ : , invr [ i ] ] \qquad ( 8 )$$

$$scale [ : , j ] = {scale}_{r} [ : , ⌊ invr [ j * G ] / G ⌋ ] \qquad ( 9 )$$

$$zero [ : , j ] = {zero}_{r} [ : , ⌊ invr [ j * G ] / G ⌋ ] \qquad ( 10 )$$

where invr[i]=argᵣ(r[k]=i), and └ ┘ represents rounding down.

At block 512, in some embodiments, the computing device 102 further quantizes the weights in the weight matrix 106 to convert the weights from floating points into integers. Based on the scaling factor and zero point after inverse sorting, the weights may be converted into a weight matrix Wᵢₙₜ of type int4 in a quantization manner shown in formula (11):

$${W}_{int} = clamp \{ round [ ( x - zero ) / scale ] , - 8 , 7 \} \qquad ( 11 )$$

In some embodiments, effects of the quantized model produced using the method of the present disclosure on four test sets are presented in the table below, where the four test sets include a basic Chinese test set, a Chinese test set with background sound, an English test set, and a contextual test set, with an evaluation indicator of a weighted word error rate. For comparison, results with no group reordering and results with asymmetric quantization are also shown in the table. By observing a relative loss of the quantized model compared with the original model (a positive number indicates a decrease in the loss and a negative number indicates an increase in the loss), it can be found that the quantized model presents a performance on all the four test sets that is not poorer than the original model, even having an advantage of up to 2.88% on the context test set. Without using the group reordering and asymmetric quantization involved in the present disclosure, the effects of the quantized model on all the four test sets may be degraded to some extent. Therefore, the group reordering and the asymmetric quantization may significantly reduce losses during quantization.

| | | | Basic | | |
|---|---|---|---|---|---|
| | | | Chinese | | |
| | | Basic | test set with | | |
| | | Chinese | background | English | Contextual |
| | | test set | sound | test set | test set |
| Original | Weighted word | 2.66% | 3.38% | 8.42% | 5.55% |
| model | error rate | | | | |
| Quantized | Weighted word | 2.65% | 3.35% | 8.38% | 5.39% |
| model | error rate | | | | |
| | Relative loss | 0.38% | 0.89% | 0.48% | 2.88% |
| No group | Weighted word | 2.66% | 3.38% | 8.39% | 5.48% |
| reordering | error rate | | | | |
| | Relative loss | 0.00% | 0.00% | 0.36% | 1.26% |
| Symmetric | Weighted word | 2.70% | 3.41% | 8.39% | 5.44% |
| quanti- | error rate | | | | |
| zation | Relative loss | −1.50% | −0.89% | 0.36% | 1.98% |

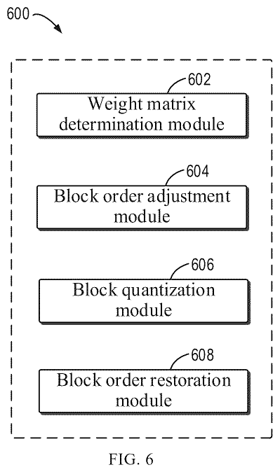

FIG. 6 is a block diagram of a quantization apparatus 600 for a speech recognition model according to some embodiments of the present disclosure. Referring to FIG. 6, the apparatus 600 comprises a weight matrix determination module 602 configured to determine a weight matrix for a network layer of the speech recognition model, where the weight matrix includes a plurality of blocks divided into a plurality of groups. The apparatus 600 further comprises a block order adjustment module 604 configured to adjust an order of the plurality of blocks in the weight matrix according to the plurality of groups and based on a plurality of block parameters of the plurality of blocks, where the block parameter indicates how much a corresponding block affects the speech recognition model. The apparatus 600 further comprises a block quantization module 606 configured to quantize the plurality of blocks in the adjusted weight matrix according to the adjusted order. In addition, the apparatus 600 further comprises a block order restoration module 608 configured to restore the order of the plurality of blocks in the quantized weight matrix.

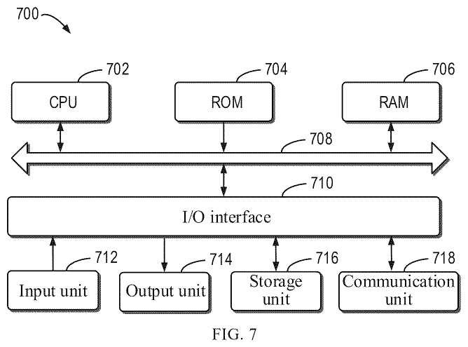

FIG. 7 is a block diagram of an electronic device 700 according to some embodiments of the present disclosure. The device 700 may be a device or an apparatus described in the embodiments of the present disclosure. As shown in FIG. 7, the device 700 comprises a central processing unit (CPU) and/or graphics processing unit (GPU) 702 that may perform a variety of appropriate actions and processing in accordance with computer program instructions stored in a read-only memory (ROM) 704 or computer program instructions loaded from a storage unit 716 into a random access memory (RAM) 706. The RAM 706 may further store various programs and data required for the operation of the device 700. The CPU/GPU 702, the ROM 704, and the RAM 706 are connected to each other via a bus 708. An input/output (I/O) interface 710 is also connected to the bus 708. Although not shown in FIG. 7, the device 700 may further comprises a coprocessor.

A number of components in the device 700 are connected to the I/O interface 710, including: an input unit 712, such as a keyboard, or a mouse; an output unit 714, such as a display, or a speaker of various types; a storage unit 716, such as a magnetic disk, or an optical disk; and a communication unit 718, such as a network card, a modem, or a wireless communication transceiver. The communication unit 718 allows the device 700 to exchange information/data with other devices over a computer network such as the Internet and/or various telecommunication networks.

Each method or process described above may be performed by the CPU/GPU 702. For example, in some embodiments, the method may be implemented as a computer software program tangibly embodied in a machine-readable medium, such as the storage unit 716. In some embodiments, some or all of the computer programs may be loaded into and/or installed onto the device 700 via the ROM 704 and/or the communication unit 718. When the computer program is loaded into the RAM 706 and executed by the CPU/GPU 702, one or more steps or actions in the method or process described above may be performed.

In some embodiments, the methods and processes described above may be implemented as a computer program product. The computer program product may include a computer-readable storage medium on which computer-readable program instructions for performing various aspects of the present disclosure are carried.

The computer-readable storage medium may be a tangible device that can hold and store instructions used by an instruction execution device. The computer-readable storage medium may be, for example, but is not limited to, an electrical storage device, a magnetic storage device, an optical storage device, an electromagnetic storage device, a semiconductor storage device, or any suitable combination thereof. More specific examples of the computer-readable storage medium (a non-exhaustive list) include: a portable computer disk, a hard disk, a random access memory (RAM), a read-only memory (ROM), an erasable programmable read-only memory (EPROM or flash memory), a static random access memory (SRAM), a portable compact disk read-only memory (CD-ROM), a digital versatile disk (DVD), a memory stick, a floppy disk, a mechanical coding device, a punched card or an in-groove raised structure on which instructions are for example stored, and any suitable combination thereof. The computer-readable storage medium used herein is not to be interpreted as a transient signal per se, such as a radio wave or another freely propagating electromagnetic wave, an electromagnetic wave propagating through a waveguide or another transmission medium (e.g., an optical pulse through a fiber-optic cable), or an electrical signal transmitted over a wire.

The computer-readable program instructions described herein may be downloaded from a computer-readable storage medium to each computing/processing device, or downloaded to an external computer or an external storage device over a network, such as the Internet, a local area network, a wide area network, and/or a wireless network. The network may include copper transmission cables, fiber-optic transmission, wireless transmission, routers, firewalls, switches, gateway computers, and/or edge servers. A network adapter card or network interface in each computing/processing device receives computer-readable program instructions from the network and forwards the computer-readable program instructions for storage in the computer-readable storage medium in each computing/processing device.

The computer program instructions for performing the operations of the present disclosure may be assembly instructions, Instruction Set Architecture (ISA) instructions, machine instructions, machine-related instructions, microcode, firmware instructions, status setting data, or source code or object code written in any combination of one or more programming languages, including object-oriented programming languages as well as conventional procedural programming languages. The computer-readable program instructions may be completely executed on a computer of a user, partially executed on a computer of a user, executed as an independent software package, partially executed on a computer of a user and partially executed on a remote computer, or completely executed on a remote computer or server. In a case of the remote computer, the remote computer may be connected to the computer of the user through any kind of network, including a local area network (LAN) or a wide area network (WAN), or may be connected to an external computer (for example, connected through the Internet with the aid of an Internet service provider). In some embodiments, an electronic circuit, such as a programmable logic circuit, a field programmable gate array (FPGA), or a programmable logic array (PLA), is personalized by using state information of the computer-readable program instructions. The electronic circuit may execute the computer-readable program instructions to implement various aspects of the present disclosure.

These computer-readable program instructions may be provided to a processing unit of a general-purpose computer, a special-purpose computer, or another programmable data processing apparatus to produce a machine, such that the instructions, when executed by the processing unit of the computer or the other programmable data processing apparatus, create an apparatus for implementing functions/actions specified in one or more blocks in the flowchart and/or the block diagrams. These computer-readable program instructions may alternatively be stored in the computer-readable storage medium. These instructions enable a computer, a programmable data processing apparatus, and/or another device to work in a specific manner. Therefore, the computer-readable medium storing the instructions includes an artifact that includes instructions for implementing various aspects of functions/actions specified in one or more blocks in the flowchart and/or the block diagrams.

Alternatively, the computer-readable program instructions may be loaded onto a computer, another programmable data processing apparatus, or another device, such that a series of operation steps are performed on the computer, the other programmable data processing apparatus, or the other device to produce a computer-implemented process. Therefore, the instructions executed on the computer, the other programmable data processing apparatus, or the other device implement functions/actions specified in one or more blocks in the flowchart and/or the block diagrams.

The flowcharts and the block diagrams in the accompanying drawings illustrate possible system architectures, functions, and operations of the device, the method, and the computer program product according to a plurality of embodiments of the present disclosure. In this regard, each block in the flowcharts or the block diagrams may represent a part of a module, a program segment, or an instruction. The part of the module, the program segment, or the instruction includes one or more executable instructions for implementing a specified logical function. In some alternative implementations, functions marked in the blocks may occur in a sequence different from that marked in the accompanying drawings. For example, two consecutive blocks may actually be executed substantially in parallel, or may sometimes be executed in a reverse order, depending on a function involved. It should also be noted that each block in the block diagrams and/or the flowcharts, and a combination of the blocks in the block diagrams and/or the flowcharts may be implemented by a dedicated hardware-based system that executes specified functions or actions, or may be implemented by a combination of dedicated hardware and computer instructions.

Various embodiments of the present disclosure have been described above. The foregoing descriptions are exemplary, not exhaustive, and are not limited to the disclosed embodiments. Many modifications and variations are apparent to a person of ordinary skill in the art without departing from the scope and spirit of the described embodiments. The terminology used in this specification is intended to best explain the principles, practical applications, or technical improvements in the market of the embodiments, or to enable others of ordinary skill in the art to understand the embodiments disclosed herein.

Some example implementations of the present disclosure are listed below.

Example 1. A quantization method for a speech recognition model, the method comprising:
determining a weight matrix for a network layer of the speech recognition model, where the weight matrix includes a plurality of blocks divided into a plurality of groups;
adjusting an order of the plurality of blocks in the weight matrix according to the plurality of groups and based on a plurality of block parameters of the plurality of blocks, where the block parameter indicates how much a corresponding block affects the speech recognition model;
quantizing the plurality of blocks in the adjusted weight matrix according to the adjusted order; and
restoring the order of the plurality of blocks in the quantized weight matrix.

Example 2. The method according to Example 1, where the adjusting an order of the plurality of blocks in the weight matrix according to the plurality of groups and based on a plurality of block parameters of the plurality of blocks comprises:
determining a first sorting result of the plurality of block parameters of the plurality of blocks in each group; and
adjusting the order of the plurality of blocks in the weight matrix according to the plurality of groups and based on a plurality of first sorting results for the plurality of groups.

Example 3. The method according to Example 1 or 2, where the adjusting the order of the plurality of blocks in the weight matrix according to the plurality of groups and based on a plurality of first sorting results for the plurality of groups comprises:
determining a group parameter of each group based on the plurality of block parameters of the plurality of blocks in each group;
determining a second sorting result of a plurality of group parameters of the plurality of groups; and
adjusting the order of the plurality of blocks in the weight matrix according to the plurality of groups and based on the plurality of first sorting results and the second sorting result for the plurality of groups.

Example 4. The method according to any one of Examples 1 to 3, where the block includes a column block, and the plurality of block parameters are determined by:
obtaining a plurality of input matrices of the network layer;
determining a second derivative matrix for the weight matrix based on products of the plurality of input matrices and a plurality of corresponding transpose matrices; and
determining the plurality of block parameters of a plurality of column blocks based on diagonal elements of the second derivative matrix.

Example 5. The method according to any one of Examples 1 to 4, where the quantizing the plurality of blocks in the adjusted weight matrix according to the adjusted order comprises:
quantizing a first column block in the plurality of column blocks in the adjusted weight matrix;
adjusting unquantized column blocks in the plurality of column blocks based on the second derivative matrix; and
updating the first column block to the first one of the unquantized column blocks.

Example 6. The method according to any one of Examples 1 to 5, where the quantizing the plurality of blocks in the adjusted weight matrix according to the adjusted order comprises:
determining a first quantization parameter for each of the plurality of groups, the first quantization parameter including at least a first scale and a first offset;
determining a group corresponding to the block; and
quantizing the block based on the first quantization parameter for the group corresponding to the block.

Example 7. The method according to any one of Examples 1 to 6, where the first scale is determined by:
determining a difference between a maximum weight and a minimum weight in each of the plurality of groups;
determining a quantization range for each group in a predetermined quantization manner; and
determining the first scale for each group based on the difference between the maximum weight and the minimum weight and the quantization range.

Example 8. The method according to any one of Examples 1 to 7, where the offset is determined by:
determining a plurality of ratios of a plurality of weights in each group to the first scale;
determining a minimum rounding result from a plurality of rounding results corresponding to the plurality of ratios in each group; and
determining the first offset for each group based on a ratio of the minimum rounding result to the first scale.

Example 9. The method according to any one of Examples 1 to 8, where the method further comprises:
generating a fake quantized block for a quantized block in each group based on the first quantization parameter for each group;
and after the restoring the order of the plurality of blocks in the quantized weight matrix, the method further comprises:
determining a second quantization parameter for the restored weight matrix, the second quantization parameter including at least a second scale and a second offset; and
quantizing the restored weight matrix based on the second quantization parameter.

Example 10. A quantization apparatus for a speech recognition model, the apparatus comprising:
a weight matrix determination module configured to determine a weight matrix for a network layer of the speech recognition model, where the weight matrix includes a plurality of blocks divided into a plurality of groups;
a block order adjustment module configured to adjust an order of the plurality of blocks in the weight matrix according to the plurality of groups and based on a plurality of block parameters of the plurality of blocks, where the block parameter indicates how much a corresponding block affects the speech recognition model;
a block quantization module configured to quantize the plurality of blocks in the adjusted weight matrix according to the adjusted order; and
a block order restoration module configured to restore the order of the plurality of blocks in the quantized weight matrix.

Example 11. The apparatus according to Example 10, where the block order adjustment module is further configured to:
determine a first sorting result of the plurality of block parameters of the plurality of blocks in each group; and
adjust the order of the plurality of blocks in the weight matrix according to the plurality of groups and based on a plurality of first sorting results for the plurality of groups.

Example 12. The apparatus according to Example 10 or 11, where the block order adjustment module is further configured to:
determine a group parameter of each group based on the plurality of block parameters of the plurality of blocks in each group;
determine a second sorting result of a plurality of group parameters of the plurality of groups; and
adjust the order of the plurality of blocks in the weight matrix according to the plurality of groups and based on the plurality of first sorting results and the second sorting result for the plurality of groups.

Example 13. The apparatus according to any one of Examples 10 to 12, where the block includes a column block, and the apparatus further comprises a block parameter determination module configured to: obtain a plurality of input matrices of the network layer;
determine a second derivative matrix for the weight matrix based on products of the plurality of input matrices and a plurality of corresponding transpose matrices; and
determine the plurality of block parameters of a plurality of column blocks based on diagonal elements of the second derivative matrix.

Example 14. The apparatus according to any one of Examples 10 to 13, where the block quantization module is further configured to:
quantize a first column block in the plurality of column blocks in the adjusted weight matrix;
adjust unquantized column blocks in the plurality of column blocks based on the second derivative matrix; and
update the first column block to the first one of the unquantized column blocks.

Example 15. The apparatus according to any one of Examples 10 to 14, where the block quantization module is further configured to:
determine a first quantization parameter for each of the plurality of groups, the first quantization parameter including at least a first scale and a first offset;
determine a group corresponding to the block; and
quantize the block based on the first quantization parameter for the group corresponding to the block.

Example 16. The apparatus according to any one of Examples 10 to 15, where the apparatus further comprises a first scale determination module configured to:
determine a difference between a maximum weight and a minimum weight in each of the plurality of groups;
determine a quantization range for each group in a predetermined quantization manner; and
determine the first scale for each group based on the difference between the maximum weight and the minimum weight and the quantization range.

Example 17. The apparatus according to any one of Examples 10 to 16, where the apparatus further comprises an offset determination module configured to:
determine a plurality of ratios of a plurality of weights in each group to the first scale;
determine a minimum rounding result from a plurality of rounding results corresponding to the plurality of ratios in each group; and
determine the first offset for each group based on a ratio of the minimum rounding result to the first scale.

Example 18. The apparatus according to any of Examples 10 to 17, further comprising:
a fake quantization module configured to generate a fake quantized block for a quantized block in each group based on the first quantization parameter for each group;
a quantization parameter determination module configured to determine a second quantization parameter for the restored weight matrix, the second quantization parameter including at least a second scale and a second offset; and
a weight matrix quantization module configured to quantize the restored weight matrix based on the second quantization parameter.

Example 19. An electronic device, comprising:
a processor; and
a memory coupled to the processor, where the memory has instructions stored therein, which, when executed by the processor, cause the electronic device to perform actions comprising:
determining a weight matrix for a network layer of the speech recognition model, where the weight matrix includes a plurality of blocks divided into a plurality of groups;
adjusting an order of the plurality of blocks in the weight matrix according to the plurality of groups and based on a plurality of block parameters of the plurality of blocks, where the block parameter indicates how much a corresponding block affects the speech recognition model;
quantizing the plurality of blocks in the adjusted weight matrix according to the adjusted order; and restoring the order of the plurality of blocks in the quantized weight matrix.

Example 20. The electronic device according to Example 19, where the adjusting an order of the plurality of blocks in the weight matrix according to the plurality of groups and based on a plurality of block parameters of the plurality of blocks comprises:
determining a first sorting result of the plurality of block parameters of the plurality of blocks in each group; and
adjusting the order of the plurality of blocks in the weight matrix according to the plurality of groups and based on a plurality of first sorting results for the plurality of groups.

Example 21. The electronic device according to Example 19 or 20, where the adjusting the order of the plurality of blocks in the weight matrix according to the plurality of groups and based on a plurality of first sorting results for the plurality of groups comprises:
determining a group parameter of each group based on the plurality of block parameters of the plurality of blocks in each group;
determining a second sorting result of a plurality of group parameters of the plurality of groups; and
adjusting the order of the plurality of blocks in the weight matrix according to the plurality of groups and based on the plurality of first sorting results and the second sorting result for the plurality of groups.

Example 22. The electronic device according to any one of Examples 19 to 21, where the block includes a column block, and the plurality of block parameters are determined by:
obtaining a plurality of input matrices of the network layer;
determining a second derivative matrix for the weight matrix based on products of the plurality of input matrices and a plurality of corresponding transpose matrices; and
determining the plurality of block parameters of a plurality of column blocks based on diagonal elements of the second derivative matrix.

Example 23. The electronic device according to any one of Examples 19 to 22, where the quantizing the plurality of blocks in the adjusted weight matrix according to the adjusted order comprises:
quantizing a first column block in the plurality of column blocks in the adjusted weight matrix;
adjusting unquantized column blocks in the plurality of column blocks based on the second derivative matrix; and
updating the first column block to the first one of the unquantized column blocks.

Example 24. The electronic device according to any one of Examples 19 to 23, where the quantizing the plurality of blocks in the adjusted weight matrix according to the adjusted order comprises:
determining a first quantization parameter for each of the plurality of groups, the first quantization parameter including at least a first scale and a first offset;
determining a group corresponding to the block; and
quantizing the block based on the first quantization parameter for the group corresponding to the block.

Example 25. The electronic device according to any one of Examples 19 to 24, where the first scale is determined by:
determining a difference between a maximum weight and a minimum weight in each of the plurality of groups;
determining a quantization range for each group in a predetermined quantization manner; and
determining the first scale for each group based on the difference between the maximum weight and the minimum weight and the quantization range.

Example 26. The electronic device according to any one of Examples 19 to 25, where the offset is determined by:
determining a plurality of ratios of a plurality of weights in each group to the first scale;
determining a minimum rounding result from a plurality of rounding results corresponding to the plurality of ratios in each group; and
determining the first offset for each group based on a ratio of the minimum rounding result to the first scale.

Example 27. The electronic device according to any one of Examples 19 to 26, where the actions further comprise:
generating a fake quantized block for a quantized block in each group based on the first quantization parameter for each group;
and after the restoring the order of the plurality of blocks in the quantized weight matrix, the actions further include:
determining a second quantization parameter for the restored weight matrix, the second quantization parameter including at least a second scale and a second offset; and
quantizing the restored weight matrix based on the second quantization parameter.

Example 28. A computer-readable storage medium having computer-executable instructions stored thereon, where the computer executable instructions are executed by a processor to implement the method according to any one of Examples 1 to 9.

Example 29. A computer program product tangibly stored on a computer-readable medium and including computer-executable instructions that, when executed by a device, cause the device to perform the method according to any one of Examples 1 to 9.

Although the present disclosure has been described in a language specific to structural features and/or logical actions of the method, it should be understood that the subject matter defined in the appended claims is not necessarily limited to the specific features or actions described above. In contrast, the specific features and actions described above are merely exemplary forms of implementing the claims.

I/We claim:

1. A quantization method for a speech recognition model, the method comprising:
determining a weight matrix for a network layer of the speech recognition model, wherein the weight matrix comprises a plurality of blocks divided into a plurality of groups;
adjusting an order of the plurality of blocks in the weight matrix according to the plurality of groups and based on a plurality of block parameters of the plurality of blocks, wherein the block parameter indicates how much a corresponding block affects the speech recognition model; and
quantizing the plurality of blocks in the adjusted weight matrix according to the adjusted order; and
restoring the order of the plurality of blocks in the quantized weight matrix.

2. The method according to claim 1, wherein adjusting an order of the plurality of blocks in the weight matrix according to the plurality of groups and based on a plurality of block parameters of the plurality of blocks comprises:
determining a first sorting result of the plurality of block parameters of the plurality of blocks in each group; and
adjusting the order of the plurality of blocks in the weight matrix according to the plurality of groups and based on a plurality of first sorting results for the plurality of groups.

3. The method according to claim 2, wherein adjusting the order of the plurality of blocks in the weight matrix according to the plurality of groups and based on a plurality of first sorting results for the plurality of groups comprises:
determining a group parameter of each group based on the plurality of block parameters of the plurality of blocks in each group;
determining a second sorting result of a plurality of group parameters of the plurality of groups; and
adjusting the order of the plurality of blocks in the weight matrix according to the plurality of groups and based on the plurality of first sorting results and the second sorting result for the plurality of groups.

4. The method according to claim 1, wherein the block comprises a column block, and the plurality of block parameters are determined by:
obtaining a plurality of input matrices of the network layer;
determining a second derivative matrix for the weight matrix based on products of the plurality of input matrices and a plurality of corresponding transpose matrices; and
determining the plurality of block parameters of a plurality of column blocks based on diagonal elements of the second derivative matrix.

5. The method according to claim 4, wherein quantizing the plurality of blocks in the adjusted weight matrix according to the adjusted order comprises:
quantizing a first column block in the plurality of column blocks in the adjusted weight matrix;
adjusting unquantized column blocks in the plurality of column blocks based on the second derivative matrix; and
updating the first column block to a first column block of the unquantized column blocks.

6. The method according to claim 1, wherein quantizing the plurality of blocks in the adjusted weight matrix according to the adjusted order comprises:
determining a first quantization parameter for each group of the plurality of groups, the first quantization parameter comprising at least a first scale and a first offset;
determining a group corresponding to the block; and
quantizing the block based on the first quantization parameter for the group corresponding to the block.

7. The method according to claim 6, wherein the first scale is determined by:
determining a difference between a maximum weight and a minimum weight in each group of the plurality of groups;
determining a quantization range for each group in a predetermined quantization manner; and
determining the first scale for each group based on the difference between the maximum weight and the minimum weight and the quantization range.

8. The method according to claim 7, wherein the offset is determined by:
determining a plurality of ratios of a plurality of weights in each group to the first scale;
determining a minimum rounding result from a plurality of rounding results corresponding to the plurality of ratios in each group; and
determining the first offset for each group based on a ratio of the minimum rounding result to the first scale.

9. The method according to claim 6, wherein the method further comprises:
generating a fake quantized block for a quantized block in each group based on the first quantization parameter for each group;
and after restoring the order of the plurality of blocks in the quantized weight matrix, the method further comprises:
determining a second quantization parameter for the restored weight matrix, the second quantization parameter comprising at least a second scale and a second offset; and
quantizing the restored weight matrix based on the second quantization parameter.

10. An electronic device, comprising:
a processor; and
a memory coupled to the processor, wherein the memory has instructions stored therein, which, when executed by the processor, cause the electronic device to:
determine a weight matrix for a network layer of the speech recognition model, wherein the weight matrix comprises a plurality of blocks divided into a plurality of groups;
adjust an order of the plurality of blocks in the weight matrix according to the plurality of groups and based on a plurality of block parameters of the plurality of blocks, wherein the block parameter indicates how much a corresponding block affects the speech recognition model; and
quantize the plurality of blocks in the adjusted weight matrix according to the adjusted order; and
restore the order of the plurality of blocks in the quantized weight matrix.

11. The electronic device according to claim 10, wherein the instructions causing the electronic device to adjust an order of the plurality of blocks in the weight matrix according to the plurality of groups and based on a plurality of block parameters of the plurality of blocks comprise instructions to:
determine a first sorting result of the plurality of block parameters of the plurality of blocks in each group; and
adjust the order of the plurality of blocks in the weight matrix according to the plurality of groups and based on a plurality of first sorting results for the plurality of groups.

12. The electronic device according to claim 11, wherein the instructions causing the electronic device to adjust the order of the plurality of blocks in the weight matrix according to the plurality of groups and based on a plurality of first sorting results for the plurality of groups comprise instructions to:
determine a group parameter of each group based on the plurality of block parameters of the plurality of blocks in each group;
determine a second sorting result of a plurality of group parameters of the plurality of groups; and
adjust the order of the plurality of blocks in the weight matrix according to the plurality of groups and based on the plurality of first sorting results and the second sorting result for the plurality of groups.

13. The electronic device according to claim 10, wherein the block comprises a column block, and the plurality of block parameters are determined by:
obtaining a plurality of input matrices of the network layer;
determining a second derivative matrix for the weight matrix based on products of the plurality of input matrices and a plurality of corresponding transpose matrices; and
determining the plurality of block parameters of a plurality of column blocks based on diagonal elements of the second derivative matrix.

14. The electronic device according to claim 13, wherein the instructions causing the electronic device to quantize the plurality of blocks in the adjusted weight matrix according to the adjusted order comprise instructions to:
quantize a first column block in the plurality of column blocks in the adjusted weight matrix;
adjust unquantized column blocks in the plurality of column blocks based on the second derivative matrix; and
update the first column block to a first column block of the unquantized column blocks.

15. The electronic device according to claim 10, wherein the instructions causing the electronic device to quantize the plurality of blocks in the adjusted weight matrix according to the adjusted order comprise instructions to:
determine a first quantization parameter for each group of the plurality of groups, the first quantization parameter comprising at least a first scale and a first offset;
determine a group corresponding to the block; and
quantize the block based on the first quantization parameter for the group corresponding to the block.

16. The electronic device according to claim 15, wherein the first scale is determined by:
determining a difference between a maximum weight and a minimum weight in each group of the plurality of groups;
determining a quantization range for each group in a predetermined quantization manner; and
determining the first scale for each group based on the difference between the maximum weight and the minimum weight and the quantization range.

17. The electronic device according to claim 16, wherein the offset is determined by:
determining a plurality of ratios of a plurality of weights in each group to the first scale;
determining a minimum rounding result from a plurality of rounding results corresponding to the plurality of ratios in each group; and
determining the first offset for each group based on a ratio of the minimum rounding result to the first scale.

18. The electronic device according to claim 15, wherein the instructions further comprise instructions to:
generate a fake quantized block for a quantized block in each group based on the first quantization parameter for each group;
and after restoring the order of the plurality of blocks in the quantized weight matrix, the instructions further comprise instructions to:
determine a second quantization parameter for the restored weight matrix, the second quantization parameter comprising at least a second scale and a second offset; and
quantize the restored weight matrix based on the second quantization parameter.

19. A computer program product, comprising computer-executable instructions, wherein the computer-executable instructions are executed by a processor to:
determine a weight matrix for a network layer of the speech recognition model, wherein the weight matrix comprises a plurality of blocks divided into a plurality of groups;
adjust an order of the plurality of blocks in the weight matrix according to the plurality of groups and based on a plurality of block parameters of the plurality of blocks, wherein the block parameter indicates how much a corresponding block affects the speech recognition model; and
quantize the plurality of blocks in the adjusted weight matrix according to the adjusted order; and
restore the order of the plurality of blocks in the quantized weight matrix.

20. The computer program product according to claim 19, wherein the computer-executable instructions comprise instructions to:
determine a first sorting result of the plurality of block parameters of the plurality of blocks in each group; and
adjust the order of the plurality of blocks in the weight matrix according to the plurality of groups and based on a plurality of first sorting results for the plurality of groups.
